(19) United States
(12) Patent Application Publication
(10) Pub. No.: US 2018/0203304 A1
(43) Pub. Date: Jul. 19, 2018

(54) METHOD FOR MANUFACTURING DISPLAY PANEL, DISPLAY PANEL AND DISPLAY APPARATUS

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Yongshan ZHOU, Beijing (CN); Jingpeng LI, Beijing (CN); Kaifei TIAN, Beijing (CN)

(73) Assignees: BOE TECHNOLOGY GROUP CO., LTD., Beijing (CN); BEIJING BOE OPTOELECTRONICS TECHNOLOGY CO., LTD., Beijing (CN)

(21) Appl. No.: 15/528,006

(22) PCT Filed: Aug. 4, 2016
(86) PCT No.: PCT/CN2016/093258

§ 371 Date: May 18, 2017

(30) Foreign Application Priority Data
Apr. 13, 2016 (CN) 201610226877.1

(51) Int. Cl. G02F 1/1337; H01L 27/12

(52) U.S. Cl. CPC G02F 1/133788; G02F 1/133514; H01L 27/1218; G02F 1/133723

(57) ABSTRACT

The present disclosure relates to a method for manufacturing a display panel, a display panel and a display apparatus. There is provided a method for manufacturing a display panel, wherein the display panel includes a first substrate, the manufacturing method including forming a first orientation layer on a first substrate, wherein the first orientation layer includes a peripheral portion on a bezel region of the first substrate and a central portion on an active region of the first substrate surrounded by the bezel region, and treating the peripheral portion of the first orientation layer to remove active functional groups in the material of the peripheral portion.

### CROSS-REFERENCE TO RELATED APPLICATIONS

This patent application is a National Stage Entry of PCT/CN2016/093258 filed on Aug. 4, 2016, which claims the benefit and priority of Chinese Patent Application No. 201610226877.1 filed on Apr. 13, 2016, the disclosures of which are incorporated by reference herein in their entirety as part of the present application.

### BACKGROUND

The present disclosure relates to the field of display technology, and in particular, to a method for manufacturing a display panel, a display panel, and a display apparatus.

With the development in recent several decades, Thin Film Transistor display (TFT-LCD) technology has been gradually mature in terms of technology and process. It has replaced Cold Fluorescent Lamp (CCFL) display and has become the mainstream product in the field of display.

In order to enable liquid crystal molecules to be properly orientated in the production of the LCD panel, it is necessary to coat one layer of an orientation layer including such as polyimide on the surface of an array substrate and a color film substrate, and then to perform an orientation treatment on the orientation layer to implement the orientation of liquid crystal molecules.

According to the current market's demand, a bezel of a panel is constantly narrowed to enhance visual beauty, but the narrowed bezel will make an outer edge of the orientation layer exposed to the outside of the sealant, and then in contact with other molecules such as water molecules in the environment, resulting in adverse effects.

### BRIEF DESCRIPTION

Embodiments of the present disclosure provide a method for manufacturing a display panel, which can effectively prevent external molecules such as water molecules from entering an inner portion of the display panel via an edge portion of the orientation layer coinciding with the sealant, thereby improving the display quality of the display panel (especially a display panel with a narrow bezel or a very narrow bezel design).

One aspect of the present disclosure-provides a method for manufacturing a display panel, wherein the display panel includes a first substrate, the method including forming a first orientation layer on a first substrate, wherein the first orientation layer includes a peripheral portion on a bezel region of the first substrate and a central portion on an active region of the first substrate surrounded by the bezel region, and treating the peripheral portion of the first orientation layer to remove active functional groups in a material of the peripheral portion.

According to an embodiment of the present disclosure, the first orientation layer includes polyimide.

According to an embodiment of the present disclosure, the first orientation layer is oriented before or after the treatment.

According to an embodiment of the present disclosure, the treatment includes at least one of a thermal treatment and an optical radiation.

According to an embodiment of the present disclosure, the treatment is performed by the optical radiation.

According to an embodiment of the present disclosure, the active region of the first orientation layer is protected from radiation through a mask during the optical radiation.

According to an embodiment of the present disclosure, the light source used in the optical radiation is the same as the light source used in the orientation of the orientation layer.

According to an embodiment of the present disclosure, the optical radiation uses a polarized light source.

According to an embodiment of the present disclosure, if a polarized light source is used, the light radiation is performed twice and the light source used in the optical radiation is rotated by 90 degrees with respect to the first substrate between the two optical radiations.

According to an embodiment of the present disclosure, the optical radiation uses ultraviolet light.

According to an embodiment of the present disclosure, the ultraviolet light has a power range of 100 to 1000 mJ/cm².

According to an embodiment of the present disclosure, a second orientation layer is formed on a second substrate, wherein the second orientation layer includes a peripheral portion on a bezel region of the second substrate and a central portion on an active region of the second substrate surrounded by the bezel region, and the peripheral portion of the second orientation layer is treated to remove active functional groups in the material of the peripheral portion.

According to an embodiment of the present disclosure, a sealant is applied on a bezel region of at least one of the first substrate and the second substrate, and the first substrate is joined with the second substrate through the sealant to form a cell.

According to an embodiment of the present disclosure, one of the first substrate and the second substrate is a TFT substrate, and the other of the first substrate and the second substrate is a CF substrate.

According to an embodiment of the present disclosure, in the bezel region, the outer edge of the peripheral portion of at least one of the first and second orientation layers is exposed.

Another aspect of the present disclosure provides a display panel, including a first substrate, a first orientation layer formed on the first substrate, wherein the first orientation layer includes a peripheral portion on a bezel region of the first substrate and a central portion on an active region of the first substrate surrounded by the bezel region, wherein active functional groups in a material of the peripheral portion of the first orientation layer are removed.

According to an embodiment of the present disclosure, the central portion of the first orientation layer is oriented.

According to an embodiment of the present disclosure, the display panel further includes a second substrate, and a second orientation layer formed on the second substrate, wherein the second orientation layer includes a peripheral portion on a bezel region of the second substrate and a central portion on an active region of the second substrate surrounded by the bezel region, wherein active functional groups in a material of the peripheral portion of the second orientation layer are removed, wherein the first substrate is joined with the second substrate through the sealant on the bezel region to form a cell.

According to an embodiment of the present disclosure, one of the first substrate and the second substrate is a TFT substrate, and the other of the first substrate and the second substrate is a CF substrate.

According to an embodiment of the present disclosure, in the bezel region, an outer edge of the peripheral portion of at least one of the first and second orientation layers is exposed.

A further aspect of the present disclosure provides a display apparatus including the above-described display panel.

### BRIEF DESCRIPTION OF THE DRAWINGS

In order to more clearly illustrate the technical solutions of the embodiments of the present disclosure, the drawings of the embodiments will be briefly described below. It should be understood that the drawings described below merely relate to some embodiments of the present disclosure rather than limit the present disclosure, in which:

FIG. 1 shows a structural diagram of a display panel;

FIG. 2 shows basic principles of the present disclosure; and

FIGS. 3A-3D show a method of manufacturing a display panel according to an embodiment of the present disclosure.

### DETAILED DESCRIPTION

To make the technical solutions and advantages of the present disclosure more clear, the technical solutions of the embodiments of the present disclosure will be clearly and completely described below in detail in conjunction with the drawings. Obviously, the embodiments described are part of embodiments of the present disclosure, but not all the embodiments. Based on the described embodiments of the present disclosure, all other embodiments obtained by those skilled in the art without creative work fall within the scope of protection sought for by the present disclosure.

The terms “a”, “one”, “this” and “the” are intended to mean the presence of one or more elements when introducing elements of the present disclosure and their embodiments. The terms “comprising”, “comprising”, “containing” and “having” are intended to be inclusive and to indicate that there may be additional elements other than the listed elements. For the purpose of the following description, the terms “upper”, “lower”, “left”, “right”, “vertical”, “horizontal”, “top”, “bottom” and derivatives thereof, shall involve the disclosure as in the denoted direction in the drawings. The terms “on”, “on top of . . . ”, “positioned on . . . ”, or “positioned on top of . . .” mean that a first element such as a first structure exists on a second element such as a second structure, where an intermediate element such as an interface structure may exist between the first element and the second element.

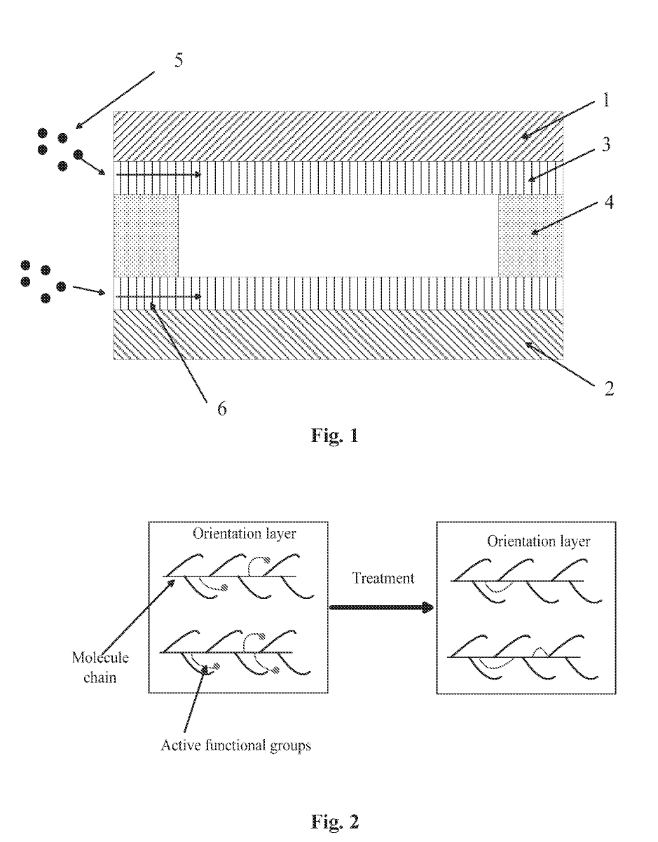

FIG. 1 shows a structural diagram of a display panel. As shown in the drawing, this display panel includes a color film (CF) substrate 1, a TFT substrate 2, an orientation layer 3 including an orientation material such as polyimide, and a sealant 4. Since the display panel has a narrow bezel design, an outer edge of the orientation layer is exposed to the external environment and then cannot be protected by the sealant. The environment molecules 5 in the external environment may enter into an inner portion of the display panel through the outer edge of the orientation layer, as denoted by a entry path 6, thereby resulting in adverse effects. For example, if water molecules in the external environment enter the inner portion of the display panel along the path 6, a display abnormity may be caused on a periphery region of the display panel, for example, the Mura problem.

To this end, the inventors of the present disclosure have made extensive studies. It has been found through researches that active functional groups produced during the formation of the orientation layer are the main reason for formation of the path 6 due to the fact that the material used in the orientation layer is usually an organic material. Thus, by removing the active functional groups of the orientation layer in the peripheral region, the formation of the entry path 6 can be effectively prevented, thereby solving the above problem.

FIG. 2 further shows a basic principle of the present disclosure. Specifically, for example, a left side of FIG. 2 shows the active functional groups present in the orientation material of the orientation layer such as polyimide. The active functional groups are usually located in molecular chains of the orientation material. In general, the active functional groups are residual active functional groups produced in formation of the orientation layer. With treatments such as thermaling or optical radiation so that the active functional groups are broken or closed, the active functional groups are thus removed, as shown in the right side of FIG. 2. In this way, external environment molecules cannot pass via the active functional groups, that is, cannot enter the active region (i.e., the display region). As a result, requirements for a very narrow bezel design are met, and qualities of the product is further enhanced.

In order to prevent the formation of the entry path, based on the abovementioned principle, an embodiment of the present disclosure provides a method for manufacturing a display panel, wherein the display panel includes a first substrate, the manufacturing method including forming a first orientation layer on a first substrate, wherein the first orientation layer includes a peripheral portion on a bezel region of the first substrate and a central portion on an active region of the first substrate surrounded by the bezel region, and treating the peripheral portion of the first orientation layer to remove active functional groups in the material of the peripheral portion.

One embodiment of the method for manufacturing the display panel of the present disclosure will be described below with reference to the accompanying drawings.

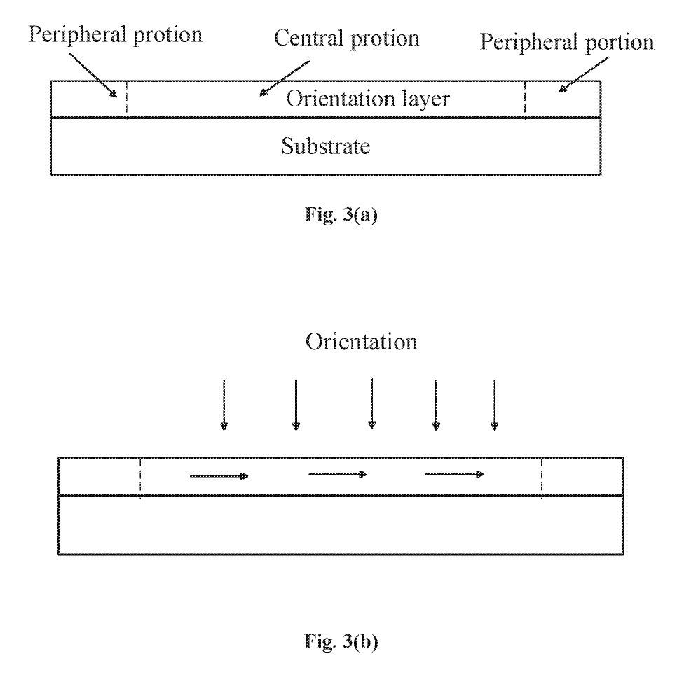

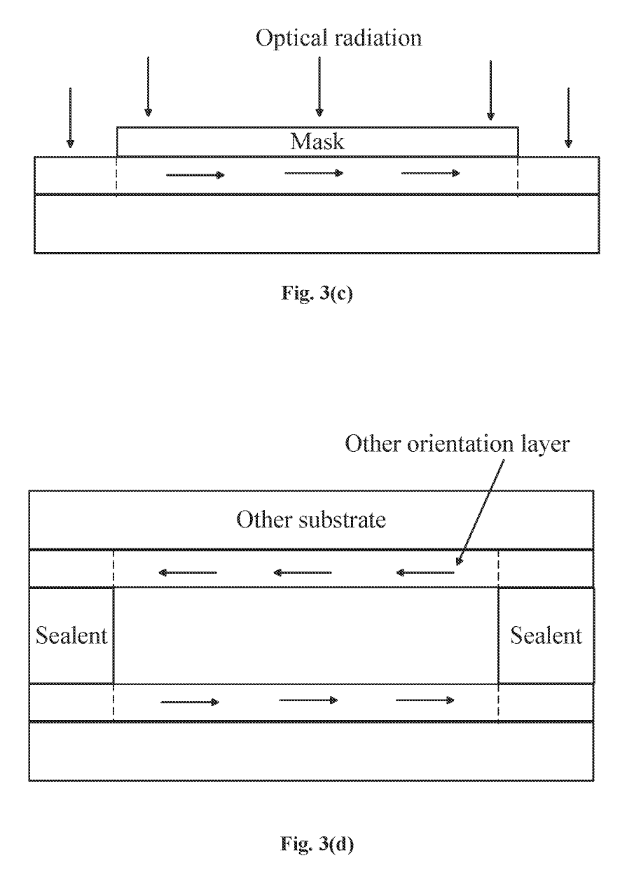

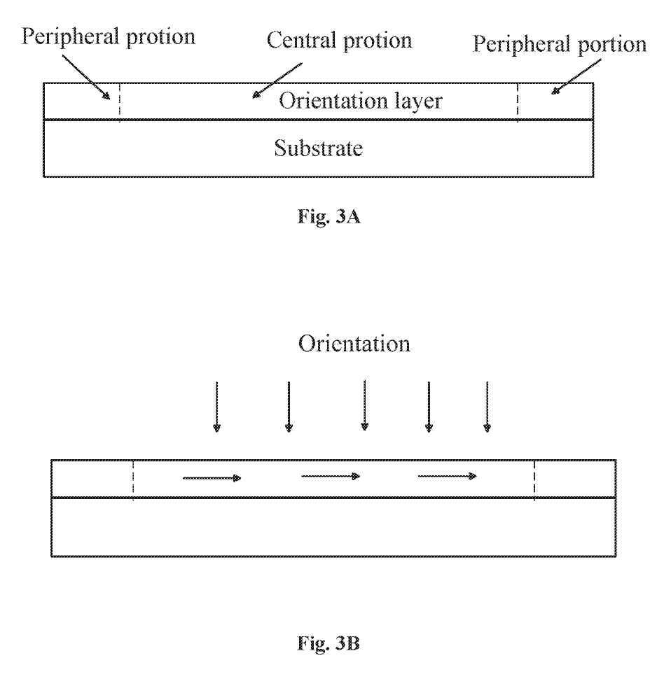

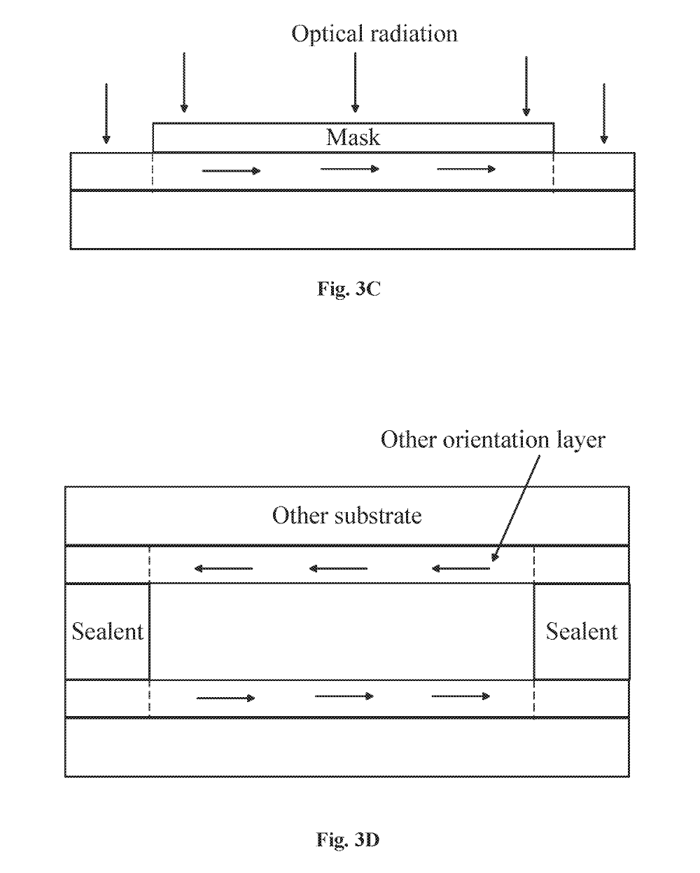

FIGS. 3A-3D show the method for manufacturing a display panel according to an embodiment of the present disclosure.

First, as shown in FIG. 3A, an orientation layer is provided on a substrate, and the substrate may be any one of a TFT substrate and a color film (CF) substrate. It is to be understood that the embodiments of the present disclosure are not limiting of the material of the orientation layer, including any orientation material that may be used for liquid crystal display. Preferably, the orientation layer includes polyimide. For ease of explanation of the principles of the present disclosure, the substrate according to the embodiment of the present disclosure may be defined to include a bezel region and an active region surrounded by the bezel region, for example, a display region. Accordingly, the orientation layer includes a peripheral portion on the bezel region of the substrate and a central portion on the active region of the substrate.

Next, as shown in FIG. 3B, an orientation treatment is performed on the orientation layer. The orientation treatment may include conventional friction orientation or optical orientation in the art.

Next, as shown in FIG. 3C, the peripheral portion of the first orientation layer is treated to remove the active functional groups in the material of the peripheral portion. The treatment includes at least one of a thermal treatment and an optical radiation. Since the thermal treatment usually can only implement the closing of part of the active functional groups, the optical radiation is preferred. In particular, for photosensitive active functional groups, the optical radiation can make them directly closed, for non-photosensitive active functional groups, the optical radiation can make them broken and the broken functional groups will subsequently volatilize.

The embodiment of the present disclosure does not particularly limit the wavelength range of optical radiation, where ultraviolet (UV) light may be used. In one embodiment, the power range of ultraviolet light is 100 to 1000 mJ/cm².

According to an embodiment of the present disclosure, the light source used in the optical radiation treatment includes a polarized light source or a non-polarized light source. In view of the directivity of the photosensitive functional groups, a non-polarized light source is preferred in order to remove photosensitive functional groups having photosensitivity in different directions as much as possible. If a polarized light source (e.g., a linearly polarized light source) is used, the optical radiation is may be performed twice, and the light source and the substrate are rotated by 90 degrees with respect to each other between the two optical radiations. For example, according to an embodiment of the present disclosure, a one-time radiation scan may be performed first, and then a second radiation scan may be performed after the substrate is rotated by 90 degrees.

According to an embodiment of the present disclosure, in order not to further increase equipment costs, the optical radiation treatment for removing the active functional groups preferably uses the same light source as the light source used when orienting the orientation layer. The light source may be an ultraviolet linearly polarized light source.

According to an embodiment of the present disclosure, the active region of the first orientation layer is prevented from radiation through a mask during the above-described optical radiation, thereby avoiding the adverse effects of the optical radiation on the direction of the orientation layer. In particular, FIG. 3C shows the case where the optical radiation treatment is performed using a mask.

It is to be understood that the above-described treatment for the removal of active functional groups may also be performed prior to the orientation treatment of the orientation layer provided that the treatment has no adverse effects on the subsequent orientation treatment or that the effects are negligible. This can be easily achieved, for example, by protecting the central region of the orientation layer with the use of a mask during the optical radiation.

Next, in addition, the method according to an embodiment of the present disclosure further includes forming another orientation layer (this step is not shown) on another substrate, wherein the other orientation layer includes a peripheral portion on a bezel region of the other substrate and a central portion on an active region surrounded by the bezel region of the other substrate, and treating the peripheral portion of the other orientation layer to remove active functional groups in a material of the peripheral portion. The other substrate is the other one of the TFT substrate and the color film (CF) substrate. That is, if the previously described substrate is a TFT substrate, then the other substrate is a color film substrate, if the previously described substrate is a color film substrate, then the other substrate is a TFT substrate.

Next, additionally, as shown in FIG. 3D, the method according to the embodiment of the present disclosure further includes applying a sealant on the bezel region of at least one of the two substrates, and then the two substrates are joined together by the sealant to form a cell. After the join, the sealant is preferably cured. The curing may include first performing optical curing to cure photosensitive components in the sealant, for example, curing part of the sealant through a short-time optical radiation, and then performing thermal treatment in a furnace to completely cure the uncured sealant, thereby completing a cell-forming process.

According to an embodiment of the present disclosure, with respect to the narrow bezel design, an outer edge of the peripheral portion of at least one of the orientation layers formed on the two substrates is exposed in the bezel region, as shown in FIG. 3D.

In addition, the embodiment of the present disclosure further provides a display panel including a substrate, an orientation layer formed on the substrate, wherein the orientation layer includes a peripheral portion on a bezel region of the substrate and a central portion on an active region of the substrate surrounded by the bezel region, wherein the active functional groups in a material of the peripheral portion of the orientation layer are removed.

According to an embodiment of the present disclosure, the central portion of the orientation layer is oriented.

According to an embodiment of the present disclosure, the display panel further includes another substrate, and another orientation layer formed on the other substrate, wherein the other orientation layer includes a peripheral portion on a bezel region of the other substrate and a central portion on an active region of the other substrate surrounded by the bezel region, wherein the active functional groups in a material of the peripheral portion of the other orientation layer are removed. Wherein the two substrates are joined together by the sealant on the bezel regions of the two substrates to form a cell.

According to an embodiment of the present disclosure, one of the two substrates is a TFT substrate and the other is a CF substrate.

According to an embodiment of the present disclosure, an outer edge of the peripheral portion of at least one of the orientation layers respectively formed on the two substrates is exposed in the bezel region.

Accordingly, an embodiment of the present disclosure further provides a display apparatus including the above-described display panel. The display apparatus includes, but is not limited to, any product or component having a display function such as a mobile phone, a tablet computer, a television set, a monitor, a notebook computer, a digital photo frame, a navigator, or the like.

Some particular embodiments have been described, and these embodiments are presented by way of example only and are not intended to limit the scope of the present disclosure. In fact, the novel embodiments described herein may be embodied in various other forms, furthermore, various omissions, substitutions and alterations in the form of embodiments described herein may be made without departing from the spirit of the disclosure. The appended claims and their equivalents are intended to cover such forms or modifications which fall within the spirit and scope of the present disclosure.

1. A method for manufacturing a display panel, wherein the display panel comprises a first substrate, the manufacturing method comprising:
forming a first orientation layer on a first substrate, wherein the first orientation layer comprises a peripheral portion on a bezel region of the first substrate and a central portion on an active region of the first substrate surrounded by the bezel region; and
treating the peripheral portion of the first orientation layer to remove active functional groups in a material of the peripheral portion.

2. The method according to claim 1, wherein the first orientation layer comprises polyimide.

3. The method according to claim 1, wherein the first orientation layer is oriented before or after the treatment.

4. The method according to claim 1, wherein the treatment comprises at least one of a thermal treatment and an optical radiation.

5. The method according to claim 4, wherein the treatment is performed by the optical radiation.

6. The method according to claim 5, wherein the active region of the first orientation layer is protected from radiation through a mask during the optical radiation.

7. The method according to claim 5, wherein the light source used in the optical radiation is the same as the light source used in the orientation of the orientation layer.

8. The method according to claim 5, wherein the optical radiation uses a polarized light source.

9. The method according to claim 8, wherein the light radiation is performed twice and the light source used in the optical radiation is rotated by 90 degrees with respect to the first substrate between the two optical radiations.

10. The method according to claim 5, wherein the optical radiation uses ultraviolet light.

11. The method according to claim 10, wherein the ultraviolet light has a power range of 100 to 1000 mJ/cm².

12. The method according to claim 1, wherein a second orientation layer is formed on a second substrate, wherein the second orientation layer comprises a peripheral portion on a bezel region of the second substrate and a central portion on an active region of the second substrate surrounded by the bezel region, and wherein the peripheral portion of the second orientation layer is treated to remove active functional groups in the material of the peripheral portion.

13. The method according to claim 12, wherein a sealant is applied on the bezel region of at least one of the first substrate and the second substrate, and wherein the first substrate is joined with the second substrate through the sealant to form a cell.

14. (canceled)

15. The method according to claim 12, wherein in the bezel region, an outer edge of the peripheral portion of at least one of the first and second orientation layers is exposed.

16. A display panel comprising:
a first substrate;
a first orientation layer formed on the first substrate, wherein the first orientation layer comprises a peripheral portion on a bezel region of the first substrate and a central portion on an active region of the first substrate surrounded by the bezel region, and wherein active functional groups in a material of the peripheral portion of the first orientation layer are removed.

17. The display panel according to claim 16, wherein the first orientation layer comprises polyimide.

18. The display panel according to claim 16, wherein the central portion of the first orientation layer is oriented.

19. The display panel according to claim 16, further comprising a second substrate, and a second orientation layer formed on the second substrate, wherein the second orientation layer comprises a peripheral portion on a bezel region of the second substrate and a central portion on an active region of the second substrate surrounded by the bezel region, wherein active functional groups in the material of the peripheral portion of the second orientation layer are removed, and wherein the first substrate is joined with the second substrate through the sealant on the bezel region to form a cell.

20. (canceled)

21. The display panel according to claim 19, wherein in the bezel region, an outer edge of the peripheral portion of at least one of the first and second orientation layers is exposed.

22. A display apparatus comprising the display panel according to claim 16.
